(19) United States
(12) Patent Application Publication
(10) Pub. No.: US 2025/0073570 A1
(43) Pub. Date: Mar. 6, 2025

(54) WIRELESS POWERED LUMINOUS PUZZLE

(71) Applicant: Foshan Jiepin intelligent Technology Group Co., LTD, Foshan (CN)

(72) Inventors: ZHI HUANG, Foshan (CN); ZHENJIANG QU, Foshan (CN)

(21) Appl. No.: 18/612,095

(22) Filed: Mar. 21, 2024

(30) Foreign Application Priority Data
Aug. 30, 2023 (CN) 202311111500.8

(51) Int. Cl. A63F 9/10; A63F 9/06; A63F 9/24; F21V 33/00; F21Y 115/10

(52) U.S. Cl. CPC A63F 9/10; A63F 9/0612; A63F 9/24; F21V 33/008; A63F 2009/1066; A63F 2009/2454; A63F 2009/2492; F21Y 2115/10

(57) ABSTRACT

A wireless powered luminous puzzle is provided, which includes a positioning base plate and several puzzle modules; each puzzle modules includes: a PVC board, a paper board, and a TPE board; an interior of the paper board is embedded with a LED module; an interior of the positioning base plate is provided with a power supply circuit; the power supply circuit is inductively connected to the LED module. In summary, the present application provides a luminous puzzle that can be induced by a wireless coil to emit light from puzzle blocks. Compared with a luminous puzzle in existing technology, the present application effectively protects the PCB inside the puzzle module by embedding the LED module into the paper board of the puzzle module, improves a seismic performance of the puzzle module, and avoid loosening and damage of the LED module.

### CROSS-REFERENCE TO RELATED APPLICATIONS

This application claims priority to Chinese Patent Application No. 202311111500.8, filed on Aug. 30, 2023, which is hereby incorporated by reference in its entirety.

### TECHNICAL FIELD

The present disclosure relates to the field of jigsaw puzzle device technologies, and in particular, to a wireless powered luminous puzzle.

### BACKGROUND

In existing technology, jigsaw puzzles are a popular intellectual game with various variations and varying levels of difficulty. However, in an actual assembly process, a splicing structure on puzzle blocks is required to achieve mutual splicing of the puzzles.

Chinese invention patent (application number: 2019222418395) proposes a jigsaw device based on a multi harmonic oscillation circuit, which includes a circuit board, a puzzle module, a multi harmonic oscillation circuit, and a power circuit. Two or more jigsaw positions are provided on the circuit board, a lower contact point is provided on the jigsaw position to connect to the circuit board. The puzzle module includes puzzle blocks with the same number of puzzle positions; the jigsaw block includes a puzzle base, a component, and a puzzle cover; the puzzle base has a storage chamber inside, the component is provided in the storage chamber. Pins of the components extend out of the puzzle base, the cover on the puzzle base is provided on the puzzle base. The cover on the puzzle base is provided with a puzzle pattern; and the component is a component or wire in the multi harmonic oscillation circuit.

By using this device, when the puzzle is placed correctly, the pins on the puzzle module contact with the lower contacts on corresponding puzzle positions, which can provide electricity to the device in the puzzle module and achieve illumination.

However, the device still has the following defects: 1. The puzzle module is connected to the circuit board through pins and contacts, which can easily cause a short circuit when the contacts contact with metal objects. 2. The puzzle module adopts a chamber structure, in a case of being subjected to an impact, interior components are prone to loosening.

### SUMMARY

The purpose of the present disclosure is to disclose a wireless powered luminous puzzle, which solves the problems of being prone to cause a short circuit and easy loosening of interior components in existing puzzle devices.

To achieve the above objectives, the present disclosure adopts the following technical solution:

A wireless powered luminous puzzle, including: a positioning base plate and several puzzle modules; each puzzle modules includes: a PVC board, configured to enhance a strength of the puzzle module; a paper board, and a TPE board, configured to print a pattern; a top surface of the PVC board is fixedly connected to a bottom surface of the paper board; a top surface of the paper board is fixedly connected to a bottom surface of the TPE board; an interior of the paper board is embedded with a LED module; an interior of the positioning base plate is provided with a power supply circuit; the power supply circuit is inductively connected to the LED module.

In an embodiment of the present disclosure, the LED module includes a first induction coil, a current limit resistor, a filtering capacitor, a light-emitting diode, and a PCB circuit board; two ends of the first induction coil are respectively connected to two ends of the filtering capacitor; a cathode of the light-emitting diode is connected to one end of the filtering capacitor, an anode of the light-emitting diode is connected to the other end of the filtering capacitor after passing through the current limit resistor; the first induction coil, the current limit resistor, the filtering capacitor, and the light-emitting diode are all fixedly connected to the PCB circuit board.

In an embodiment of the present disclosure, an incised groove is provided on the PCB circuit board; the first induction coil is accommodated in the incised groove.

In an embodiment of the present disclosure, the power supply circuit includes: a switch module configured to connect to an external power source, a boost module configured to adjust a power supply voltage of the circuit, a high frequency oscillation module, an amplification-and-transmission module, a second induction coil configured to inductively connect with the puzzle module, and an indicator light module configured to indicate a working state of the circuit; an output end of the switch module is connected to an input end of the boost module; an output end of the boost module is connected to a 12V voltage terminal; a first output end of the high frequency oscillation module is connected to an input end of the amplification-and-transmission module; an output end of the amplification-and-transmission module is connected to an input end of the second induction coil; a control end of the indicator light module is connected to a second output end of the high frequency oscillation module.

In an embodiment of the present disclosure, the high frequency oscillation module includes: a latch chip, a first resistor, a second resistor, a third resistor, a fourth resistor, a fifth resistor, a first capacitor, a second capacitor, a third capacitor, a fourth capacitor, a fifth capacitor, and a crystal oscillator; a first pin of the latch chip is connected to a 5V voltage terminal after passing through the first resistor and the second resistor; the first pin of the latch chip is further grounded after passing through the first capacitor; the first pin of the latch chip is further connected to the control end of the indicator light module; a second, fourth, sixth, eighth, and ninth pins of the latch chip are all connected to one end of the crystal oscillator after passing through the third resistor; one end of the crystal oscillator is further grounded after passing through the third capacitor, the other end of the crystal oscillator is grounded after passing through the fourth capacitor, the other end of the crystal oscillator is grounded after passing through the fifth capacitor; a tenth pin of the latch chip is grounded; an eleventh pin of the latch chip is connected to the other end of the crystal oscillator after passing through the fourth resistor; a thirteenth, fifteenth, and seventeenth pins of the latch chip are all connected to a nineteenth pin thereof; a twelfth, fourteenth, sixteenth, and eighteenth pins of the latch chip are all connected to the amplification-and-transmission module after passing through the fifth resistor; a twentieth pin of the latch chip is grounded after passing through the second capacitor; the twentieth pin of the latch chip is further connected to the 5V voltage terminal.

In an embodiment of the present disclosure, the amplification-and-transmission module includes: a sixth capacitor, a seventh capacitor, an eighth capacitor, a ninth capacitor, a tenth capacitor, an eleventh capacitor, a twelfth capacitor, a thirteenth capacitor, a fourteenth capacitor, a fifteenth capacitor, a sixteenth capacitor, a seventeenth capacitor, a sixth resistor, a first inductor, a second inductor, a third inductor and a first MOS transistor; a gate of the first MOS transistor is grounded after passing through the sixth resistor; the gate of the first MOS transistor is further connected to an output end of the high frequency oscillation module; a source electrode of the first MOS transistor is grounded; a drain of the first MOS transistor is connected to a positive electrode of the first polar capacitor after passing through the first inductor; the positive electrode of the first polar capacitor is further connected to the 12V voltage terminal, a negative electrode of the first polar capacitor is grounded; the positive electrode of the first polar capacitor is further grounded after passing through the seventh capacitor, the positive electrode of the first polar capacitor is further grounded after passing through the sixth capacitor; a drain of the first MOS transistor is grounded after passing through the eighth capacitor, the drain of the first MOS transistor is grounded after passing through the ninth capacitor; the drain of the first MOS transistor is connected to one end of the second inductor; the other end of the second inductor is grounded after passing through the tenth capacitor; the other end of the second inductor is grounded after passing through the eleventh capacitor; the other end of the second inductor is grounded after passing through the twelfth capacitor; the other end of the second inductor is further connected to one end of the third inductor; the other end of the third inductor is grounded after passing through the thirteenth capacitor; the other end of the third inductor is grounded after passing through the fourteenth capacitor; the other end of the third inductor is connected to the second induction coil after passing through the fifteenth capacitor; the other end of the third inductor is connected to the second induction coil after passing through the sixteenth capacitor.

In an embodiment of the present disclosure, the boost module includes: a voltage regulation chip, a first diode, a second diode, a third diode, a second polar capacitor, a third polar capacitor, a fourth inductor, a first transistor, a second transistor, a seventeenth capacitor, an eighteenth capacitor, a nineteenth capacitor, a twentieth capacitor, a twenty first capacitor, a twenty second capacitor, a twenty third capacitor, a seventh resistor, an eighth resistor, a ninth resistor, a tenth resistor, an eleventh resistor, a twelfth resistor, a thirteenth resistor, a fourteenth resistor, a fifteenth resistor, a sixteenth resistor, a seventeenth resistor, an eighteenth resistor, a nineteenth resistor; a first pin of the voltage regulation chip is grounded after passing through the sixteenth resistor; the first pin of the voltage regulation chip is connected to a collector of the first transistor after passing through the fifteenth resistor, the first pin of the voltage regulation chip is connected to a collector of the second transistor after passing through the seventeenth resistor; an emitter of the first transistor is grounded, an emitter of the second transistor is grounded; a base of the first transistor is grounded after passing through the thirteenth resistor; the base of the first transistor is further connected to the switch module after passing through the twelfth resistor; a base of the second transistor is grounded after passing through the eighteenth resistor, the base of the second transistor is further connected to the switch module after passing through the nineteenth resistor; a second pin of the voltage regulation chip is respectively connected to a cathode of the first diode, a cathode of the second diode, and a cathode of the third diode; a second pin of the voltage regulation chip is connected to the first pin of the voltage regulation chip after passing through the fourteenth resistor; the second pin of the voltage regulation chip is grounded after passing through the twenty third capacitor, the second pin of the voltage regulation chip is connected to a positive electrode of the third polar capacitor, a negative electrode of the third polar capacitor is grounded; the second pin of the voltage regulation chip is further connected to the 12V voltage terminal; a third pin of the voltage regulation chip is connected to the 5V voltage terminal after passing through the eighth resistor; the third pin of the voltage regulation chip is grounded after sequentially passing through the eighth resistor and the seventeenth capacitor; the third pin of the voltage regulation chip is connected to a positive electrode of the second polar capacitor after passing through the eighth resistor, a negative electrode of the second polar capacitor is grounded; a fourth pin of the voltage regulation chip is respectively connected to an anode of the first diode, an anode of the second diode, an anode of the third diode; the fourth pin of the voltage regulation chip is connected to the positive electrode of the second polar capacitor after passing through the fourth inductor, the fourth pin of the voltage regulation chip is grounded after sequentially passing through the seventh resistor and the eighteenth capacitor; a fifth pin of the voltage regulation chip is grounded after passing through the twentieth capacitor; the fifth pin of the voltage regulation chip is grounded after passing through the ninth resistor; a sixth pin of the voltage regulation chip is grounded after passing through the tenth resistor; a seventh pin of the voltage regulation chip is grounded after sequentially passing through the eleventh resistor and the twenty first capacitor; the seventh pin of the voltage regulation chip is further grounded after passing through the twenty second capacitor; an eighth pin of the voltage regulation chip is grounded after passing through the nineteenth capacitor.

In an embodiment of the present disclosure, the switch module includes: a switch control chip, a normally open fuse switch, a Zener diode, a second MOS transistor, a twentieth resistor, a twenty fourth capacitor, and a connector configured to connect an external circuit; a first pin of the switch control chip is grounded; a second pin of the switch control chip is connected to a second pin of the connector; a third pin of the switch control chip is connected to a first pin of the connector; a fourth pin and seventh pin of the switch control chip are both connected to the boost module; a fifth pin of the switch control chip is grounded after passing through the normally open fuse switch; a sixth pin of the switch control chip is connected to a gate of the second MOS transistor, a source electrode of the second MOS transistor is connected to a fourth pin of the connector; a drain of the second MOS transistor is connected to the 5V voltage terminal; an eighth pin of the switch control chip is connected to the fourth pin of the connector; the eighth pin of the switch control chip is grounded after passing through the twenty fourth capacitor, the eighth pin of the switch control chip is further connected to a cathode of the Zener diode, an anode of the Zener diode is grounded; a third pin of the connector is grounded.

In an embodiment of the present disclosure, the indicator light module includes: a third transistor, a twenty first resistor, a twenty second resistor, and an indicator light diode; a base of the third transistor is connected to the high frequency oscillation module after passing through the twenty first resistor; a collector of the third transistor is connected to the 5V voltage terminal; an emitter of the third transistor is connected to an anode of the indicator light diode after passing through the twenty second resistor, a cathode of the indicator light diode is grounded.

Compared with existing technology, the beneficial effects of the present disclosure are:

The present disclosure provides a wireless powered luminous puzzle, which includes a positioning base plate and several puzzle modules; each puzzle modules includes a PVC board configured to enhance a strength of the puzzle module, a paper board, and a TPE board configured to print a pattern; a top surface of the PVC board is fixedly connected to a bottom surface of the paper board; a top surface of the paper board is fixedly connected to a bottom surface of the TPE board; an interior of the paper board is also embedded with a LED module; an interior of the positioning base plate is provided with a power supply circuit; which is inductively connected to the LED module. In summary, the present application provides a luminous puzzle that can be induced by a wireless coil to emit light from puzzle blocks. Compared with the luminous puzzle in existing technology, the present application effectively protects the PCB inside the puzzle module by embedding the LED module into the paper board of the puzzle module, improves a seismic performance of the puzzle module, avoids loosening and damage of the LED module component. An energy transfer principle on the puzzle is changed from an original contact connection to a coil induction energy transfer, which can avoid a short circuit of metal contact and improve a lifespan of the puzzle.

### BRIEF DESCRIPTION OF DRAWINGS

In order to provide a clearer explanation of the technical solution in the embodiments of the present disclosure, a brief introduction will be given below to the drawings required in the description of the embodiments. It is obvious that the drawings in the following description are only some embodiments of the present disclosure. For those skilled in the art, other drawings can be obtained based on these drawings without creative work.

FIG. 1 is a schematic diagram of an interior hierarchical structure of a puzzle module.

FIG. 2 is a PCB board layout diagram of a LED module.

FIG. 3 is a schematic diagram of a high frequency oscillation module circuit.

FIG. 4 is a schematic diagram of an amplification-and-transmission module circuit.

FIG. 5 is a schematic diagram of a boost module circuit.

FIG. 6 is a schematic diagram of a switch module circuit.

FIG. 7 is a schematic diagram of an indicator light module circuit.

Numeral reference: 1. PVC board; 2. Paper board; 3. TPE board; 4. LED module.

### DESCRIPTION OF EMBODIMENTS

In the present disclosure, unless otherwise specified and limited terms “installation”, “connection to”, “connection with”, “fixation” and other terms should be broadly understood, for example, they can be a fixed connection, a detachable connection, or an integrated connection; it can be a mechanical connection or an electrical connection; it can be directly connected, or indirectly connected through an intermediate medium, or it can be an interior connection between two components. For ordinary technical personnel in this field, the specific meanings of the above terms in the present disclosure can be understood based on a specific circumstance. Terms “first” and “second” are only used to describe a purpose and cannot be understood as indicating or implying a relative importance or implying the number of technical features indicated. Therefore, the features limited to “first” and “second” can explicitly or implicitly include one or more of these features.

In the present disclosure, unless otherwise explicitly defined and limited, a first feature may include a direct contact between the first and second features, or a direct contact between the first and second features through other features between them, either above or below the second feature. Moreover, the first feature “above”, “on”, and “up” in the second feature include that the first feature is directly above and diagonally above the second feature, or simply indicating that the first feature is horizontally higher than the second feature. The first feature “under”, “below”, and “down” include that the first feature is directly below and diagonally below the second feature, or simply indicate that a horizontal height of the first feature is less than that of the second feature. Terms “vertical”, “horizontal”, “left”, “right”, “up”, “down”, and similar expressions are for illustrative purposes only, and do not indicate or imply that the device or component referred to must have a specific orientation, be constructed and operated in a specific orientation, and therefore cannot be understood as a limitation of the present disclosure.

The following will provide a clear and complete description of the technical solution in the embodiments of the present disclosure, in combination with the drawings. Obviously, the described embodiments are only a part of the embodiments of the present disclosure, not all of them.

### Embodiment 1

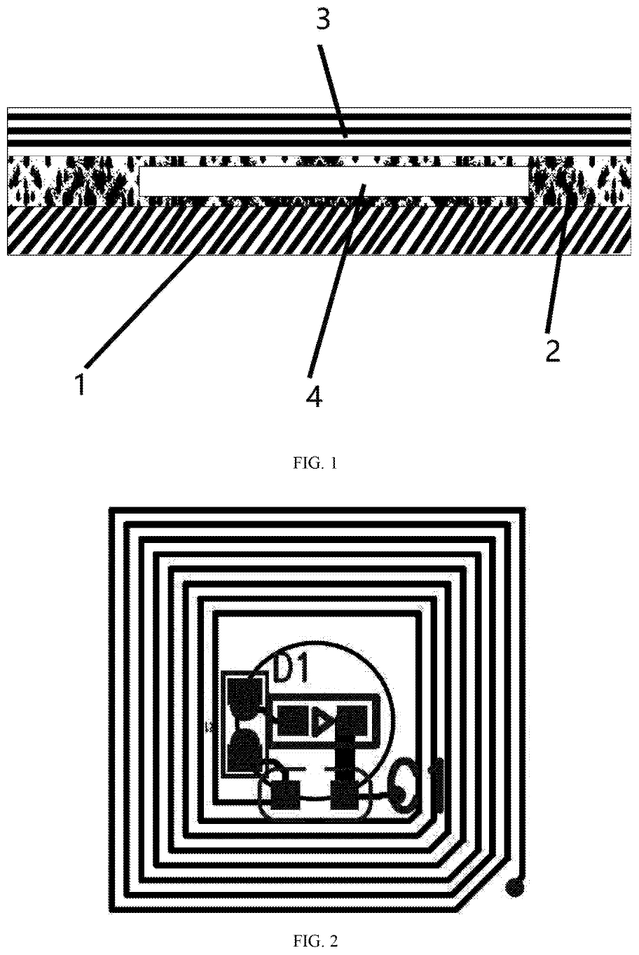

A wireless powered luminous puzzle as shown in FIGS. 1 and 2, including a positioning base plate and several puzzle modules; each of the several puzzle modules includes: a PVC board configured to enhance a strength of the puzzle module, a paper board, and a TPE board configured to print a pattern; a top surface of the PVC board is fixedly connected to a bottom surface of the paper board; a top surface of the paper board is fixedly connected to a bottom surface of the TPE board; an interior of the paper board is also embedded with an LED modules; an interior of the positioning base plate is provided with a power supply circuit; which is inductively connected to the LED module.

Specifically, in order to improve a seismic performance of the puzzle module, the present application proposes a puzzle module that utilizes an induction coil to achieve wireless illumination. In the puzzle module, multiple fixed hierarchical structures are included. The PVC board is provided below, and is used to provide support strength for the puzzle, the paper board in a middle is used to provide cushioning for the LED module, the TPE board provided above is used to print the pattern according to an actual pattern requirement, thereby providing relevant translucent lines to achieve the luminous purpose of the pattern. The interior LED module and the power supply circuit in the positioning base board sense each other. As the puzzle module does not contain a power supply, it can only emit light when the puzzle is placed on the positioning base board. In the present application, the LED module is embedded in the paper board, which can provide effective buffering protection for the LED module and provide a good fixation effect for the LED module, thereby avoiding a loosening of a component caused by collision. In the present application, electromagnetic induction power supply is used between the puzzle module and the positioning base plate below, which can avoid metal contact leakage and effectively protect the interior circuit.

In an implementation mode, as shown in FIG. 2, a PCB layout of the puzzle module of the present application, the LED module includes a first induction coil, a current limit resistor, a filtering capacitor, a light-emitting diode, and a PCB circuit board; two ends of the first induction coil are respectively connected to two ends of the filtering capacitor; a cathode of the light-emitting diode is connected to one end of the filtering capacitor, an anode of the light-emitting diode is connected to the other end of the filtering capacitor after passing through the current limit resistor; the first induction coil, current limit resistor, filtering capacitor, and light-emitting diode are all fixedly connected to the PCB circuit board. In an implementation mode, the PCB circuit board is provided with an incised groove; the first induction coil is accommodated in the incised groove. Specifically, in the present application, the first induction coil on the PCB circuit board is printed on the PCB circuit board using PCB printing, which has a higher seismic effect compared to common coils.

In an implementation mode, the power supply circuit includes a switch module for connecting to an external power source, a boost module for adjusting a power supply voltage of the circuit, a high frequency oscillation module, an amplification-and-transmission module, a second induction coil for inductive connection with the puzzle module, and an indicator light module for indicating a working state of the circuit; an output end of the switch module is connected to an input end of the boost module; an output end of the boost module is connected to a 12V voltage terminal; a first output end of the high frequency oscillation module is connected to an input end of the amplification-and-transmission module; an output end of the amplification-and-transmission module is connected to an input end of the second induction coil; a control end of the indicator light module is connected to a second output end of the high frequency oscillation module.

In the present application, the switch module is configured to connect with an external power source. The switch module can convert an input voltage into a stable 5V voltage terminal, then the boost module is used to convert the 5V voltage into a 12V voltage terminal. The high frequency oscillation module can generate an AC signal, a power of the AC signal is not enough to drive a load on the puzzle module to work after passing through the second induction coil. Therefore, the AC signal can only emit light through the second induction coil which drives the puzzle module after being amplified by the amplification-and-transmission module, as well as filtered and rectified.

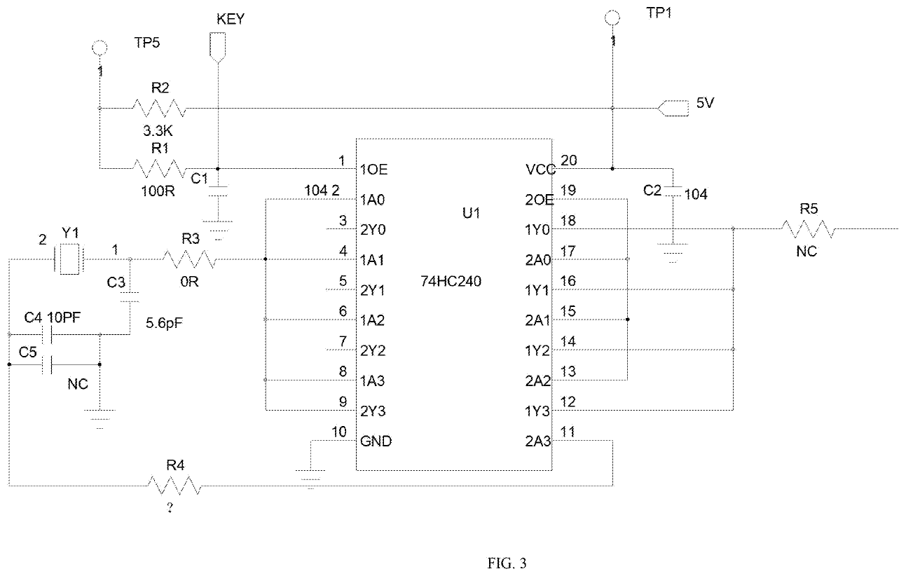

In an implementation mode, as shown in FIG. 3, the high frequency oscillation module includes a latch chip U1, a first resistor R1, a second resistor R2, a third resistor R3, a fourth resistor R4, a fifth resistor R5, a first capacitor C1, a second capacitor C2, a third capacitor C3, a fourth capacitor C4, a fifth capacitor C5, and a crystal oscillator Y1; a first pin of the latch chip U1 is connected to the 5V voltage terminal after passing through the first resistor R1 and the second resistor R2; the first pin of the latch chip U1 is further grounded after passing through the first capacitor C1; the first pin of the latch chip U1 is further connected to the control end of the indicator light module; a second, fourth, sixth, eighth, and ninth pins of the latch chip U1 are all connected to one end of the crystal oscillator Y1 after passing through the third resistor R3; one end of the crystal oscillator Y1 is further grounded after passing through the third capacitor C3, the other end of the crystal oscillator Y1 is grounded after passing through the fourth capacitor C4, the other end of the crystal oscillator Y1 is grounded after passing through the fifth capacitor C5; a tenth pin of the latch chip U1 is grounded; an eleventh pin of the latch chip U1 is connected to the other end of the crystal oscillator Y1 after passing through the fourth resistor R4; a thirteenth, fifteenth, and seventeenth pins of the latch chip U1 are all connected to a nineteenth pin; a twelfth, fourteenth, sixteenth, and eighteenth pins of the latch chip U1 are all connected to the amplification-and-transmission module after passing through the fifth resistor R; a twentieth pin of the latch chip U1 is grounded after passing through the second capacitor C2; the twentieth pin of the latch chip U1 is further connected to the 5V voltage terminal.

In the present application, the latch chip U1 adopts a latch chip model 74HC240. The input end of the latch chip U1 is connected to the crystal oscillator Y1, the output end of the latch chip U1 outputs a high frequency signal, which is then transmitted to the amplification-and-transmission module for amplification processing. The first pin of the latch chip U1 is connected to a control signal. When the control signal is input at a high level, the latch chip U1 starts working, the indicator light module can control a conduction of the transistor when it receives the high level, thereby controlling a diode of the indicator light to emit light.

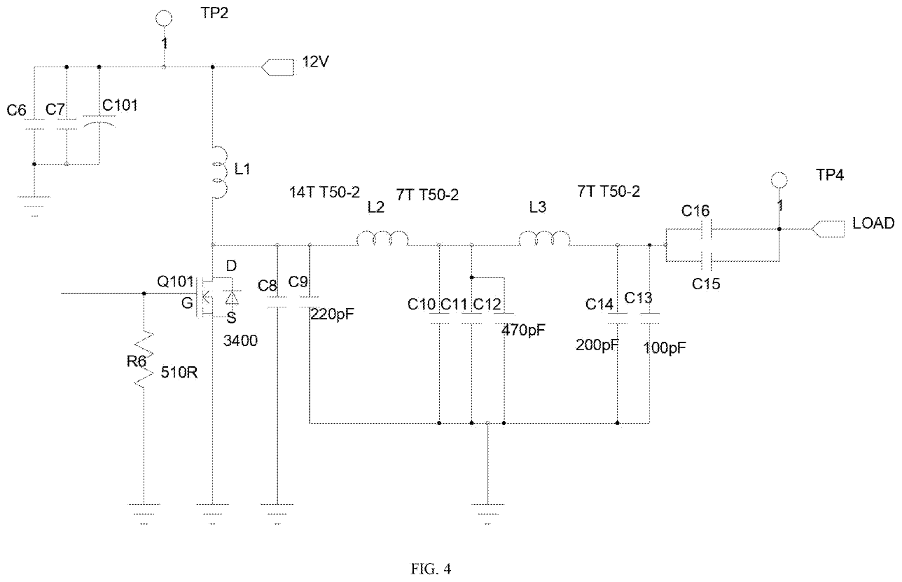

In an implementation mode, as shown in FIG. 4, the amplification-and-transmission module includes: a sixth capacitor C6, a seventh capacitor C7, an eighth capacitor C8, a ninth capacitor C9, a tenth capacitor C10, an eleventh capacitor C11, a twelfth capacitor C12, a thirteenth capacitor C13, a fourteenth capacitor C14, a fifteenth capacitor C15, a sixteenth capacitor C16, a seventeenth capacitor C17, a sixth resistor R6, a first inductor L1, a second inductor L2, a third inductor L3, and a first MOS transistor Q101; a gate of the first MOS transistor Q101 is grounded after passing through the sixth resistor R6; the gate of the first MOS transistor Q101 is further connected to an output end of the high frequency oscillation module; a source electrode of the first MOS F transistor Q101 is grounded; a drain of the first MOS transistor Q101 is connected to a positive electrode of the first polar capacitor C101 after passing through the first inductor L1; the positive electrode of the first polar capacitor C101 is further connected to the 12V voltage terminal, a negative electrode of the first polar capacitor C101 is grounded; the positive electrode of the first polar capacitor C101 is further grounded after passing through the seventh capacitor C7, the positive electrode of the first polar capacitor C101 is further grounded after passing through the sixth capacitor C6; a drain of the first MOS transistor Q101 is grounded after passing through the eighth capacitor C8, the drain of the first MOS transistor Q101 is grounded after passing through the ninth capacitor C9; the drain of the first MOS transistor Q101 is connected to one end of the second inductor L2; the other end of the second inductor L2 is grounded after passing through the tenth capacitor C10; the other end of the second inductor L2 is grounded after passing through the eleventh capacitor C11; the other end of the second inductor L2 is grounded after passing through the twelfth capacitor C12; the other end of the second inductor L2 is further connected to one end of a third inductor L3; the other end of the third inductor L3 is grounded after passing through the thirteenth capacitor C13; the other end of the third inductor L3 is grounded after passing through the fourteenth capacitor C14; the other end of the third inductor L3 is connected to the second induction coil after passing through the fifteenth capacitor C15; the other end of the third inductor L3 is connected to the second induction coil after passing through the sixteenth capacitor C16.

The gate of the first MOS transistor Q101 in the amplification-and-transmission module receives an AC signal output from the high frequency oscillation module, a switching characteristic of the MOS transistor is used, when the input is low, the first MOS transistor Q101 is cut off, an voltage output from the 12V voltage terminal is directly filtered by multiple inductors and capacitors C, which is subjected on the fifteenth capacitor C15 and the sixteenth capacitor C16, causes a +12V voltage to be set on both the fifteenth capacitor C15 and the sixteenth capacitor C16, that is to render the output end outputs a high level; in a case of high input level, the first MOS transistor Q101 conducts, the drain and source electrode of the first MOS transistor Q101 are connected to each other. Charges in the fifteenth capacitor C and the sixteenth capacitor C16 are released through the first MOS transistor Q101 to output a low level at the output end. By alternating high and low levels, a driving current is provided to the second induction coil. After receiving the AC power, the second induction coil can drive the first induction coil to work through the electromagnetic induction principle.

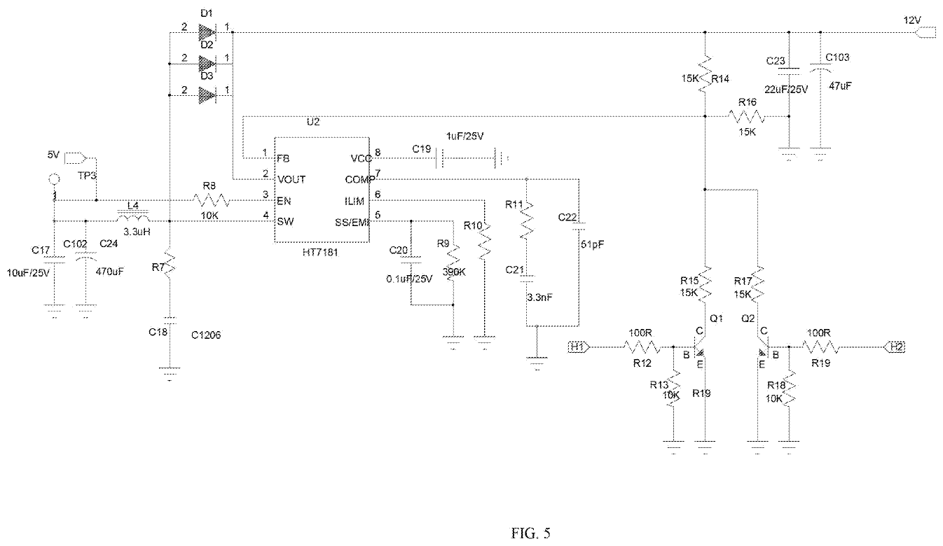

In an implementation mode, as shown in FIG. 5, the boost module includes a voltage regulation chip U2, a first diode D1, a second diode D2, a third diode D3, a second polar capacitor C102, a third polar capacitor C103, a fourth inductor L4, a first transistor Q1, a second transistor Q2, a seventeenth capacitor C17, an eighteenth capacitor C18, a nineteenth capacitor C19, a twentieth capacitor C20, a twenty first capacitor C21, a twenty second capacitor C22, and a twenty third capacitor C23, a seventh resistor R7, an eighth resistor R8, a ninth resistor R9, a tenth resistor R10, an eleventh resistor R11, a twelfth resistor R12, a thirteenth resistor R13, a fourteenth resistor R14, a fifteenth resistor R15, a sixteenth resistor R16, a seventeenth resistor R17, an eighteenth resistor R18, and a nineteenth resistor R19; a first pin of the voltage regulation chip U2 is grounded after passing through the sixteenth resistor R16; the first pin of the voltage regulation chip U2 is connected to a collector of the first transistor Q1 after passing through the fifteenth resistor R15, the first pin of the voltage regulation chip U2 is connected to a collector of the second transistor Q2 after passing through the seventeenth resistor R17; an emitter of the first transistor Q1 is grounded, an emitter of the second transistor Q2 is grounded; a base of the first transistor Q1 is grounded after passing through the thirteenth resistor R13; the base of the first transistor Q1 is further connected to the switch module after passing through the twelfth resistor R12; a base of the second transistor Q2 is grounded after passing through the eighteenth resistor R18, the base of the second transistor Q2 is further connected to the switch module after passing through the nineteenth resistor R19; a second pin of the voltage regulation chip U2 is connected to a cathode of the first diode D1, a cathode of the second diode D2, and a cathode of the third diode D3, respectively; a second pin of the voltage regulation chip U2 is connected to the first pin of the voltage regulation chip U2 after passing through the fourteenth resistor R14; the second pin of the voltage regulation chip U2 is grounded after passing through the twenty third capacitor C23. The second pin of the voltage regulation chip U2 is connected to a positive electrode of the third polar capacitor C103, a negative electrode of the third polar capacitor C103 is grounded; the second pin of the voltage regulation chip U2 is further connected to the 12V voltage terminal; a third pin of the voltage regulation chip U2 is connected to the 5V voltage terminal after passing through the eighth resistor R8; the third pin of the voltage regulation chip U2 is grounded after sequentially passing through the eighth resistor R8 and the seventeenth capacitor C17; the third pin of the voltage regulation chip U2 is connected to a positive electrode of the second polar capacitor C102 after passing through the eighth resistor R8, a negative electrode of the second polar capacitor C102 is grounded; a fourth pin of the voltage regulation chip U2 is respectively connected to an anode of the first diode D1, an anode of the second diode D2, an anode of the third diode D3; the fourth pin of the voltage regulation chip U2 is connected to the positive electrode of the second polar capacitor C102 after passing through the fourth inductor L4. The fourth pin of the voltage regulation chip U2 is grounded after sequentially passing through the seventh resistor R7 and the eighteenth capacitor C18; a fifth pin of the voltage regulation chip U2 is grounded after passing through the twentieth capacitor C20; the fifth pin of the voltage regulation chip U2 is grounded after passing through the ninth resistor R9; a sixth pin of the voltage regulation chip U2 is grounded after passing through the tenth resistor R10; a seventh pin of the voltage regulation chip U2 is grounded after sequentially passing through the eleventh resistor R11 and twenty first capacitor C21; the seventh pin of the voltage regulation chip U2 is further grounded after passing through the twenty second capacitor C22; an eighth pin of the voltage regulation chip U2 is grounded after passing through the nineteenth capacitor C19.

Specifically, in the present application, the voltage regulation chip U2 adopts a voltage regulation chip HT7181; the input end of the boost module is a third pin of the voltage regulation chip U2. A second pin of the voltage regulation chip U2 outputs a voltage of 12V after voltage regulation. A first transistor Q1 and the second transistor Q2 provide a safety function for the voltage regulation chip U2. When a fourth pin of the switch control chip U3 or a seventh pin of the switch control chip U3 outputs a low level, the first transistor Q1 is cut off, a level at the first pin of the voltage regulation chip U2 is high, when the first transistor Q1 or the second transistor Q2 is conductive, the level at the first pin of the voltage regulation chip U2 is low, which controls the voltage regulation chip U2 to stop working.

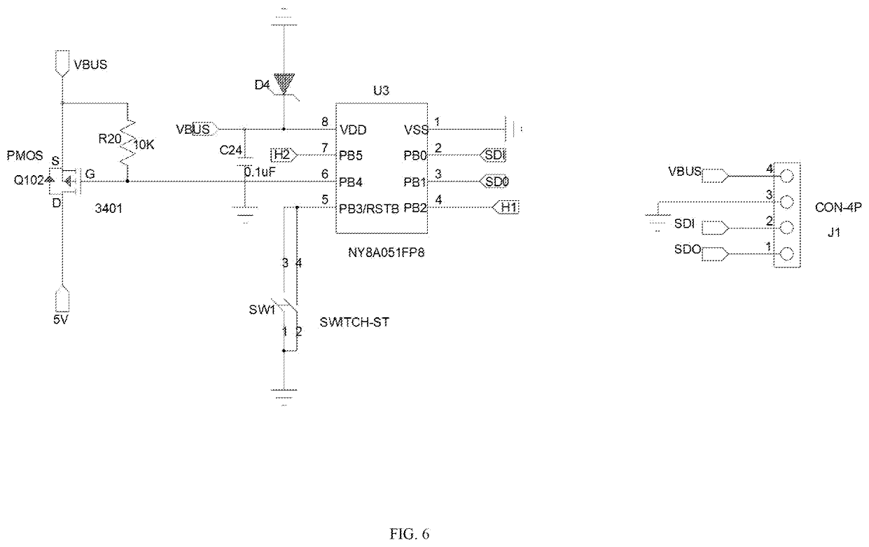

In an implementation mode, as shown in FIG. 6, the switch module includes: a switch control chip U3, a normally open fuse switch SW1, a Zener diode D4, a second MOS transistor Q102, a twentieth resistor R20, a twenty fourth capacitor C24, and a connector J1 for connecting with an external circuit. A first pin of the switch control chip U3 is grounded; a second pin of the switch control chip U3 is connected to a second pin of the connector J1; a third pin of the switch control chip U3 is connected to a first pin of the connector J1; a fourth and seventh pins of the switch control chip U3 are both connected to the boost module; a fifth pin of the switch control chip U3 is grounded after passing through the normally open fuse switch SW1; a sixth pin of the switch control chip U3 is connected to a gate of the second MOS transistor Q102, a source electrode of the second MOS transistor Q102 is connected to a fourth pin of the connector J1; a drain of the second MOS transistor Q102 is connected to the 5V voltage terminal; an eighth pin of the switch control chip U3 is connected to the fourth pin of the connector J1; the eighth pin of the switch control chip U3 is grounded after passing through the twenty fourth capacitor C24. The eighth pin of the switch control chip U3 is further connected to a cathode of the Zener diode D4, an anode of the Zener diode D4 is grounded; a third pin of the connector J1 is grounded.

In the present application, the switch control chip U3 adopts a model NY8A051FP8; a second and third pins of the switch control chip U3 are connected to an external control terminal through the connector J1. In this embodiment, the connector J1 adopts a USB interface and can achieve signal interaction with the external control device. In the second MOS transistor Q102, the drain D is connected to the output, the source electrode S is connected to the power supply. The gate G is connected to the source S through a weak pull-up resistor R for startup. When the input VBUS voltage reaches a certain value, a voltage input to the sixth pin of the switch control chip U3 exceeds a predetermined voltage, the second MOS transistor Q102 conducts, and outputs a 5V voltage at the drain D.

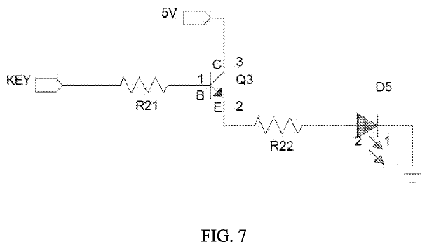

In an implementation mode, as shown in FIG. 7, the indicator light module includes: a third transistor Q3, a twenty first resistor R21, a twenty second resistor R22, and an indicator light diode D5; a base of the third transistor Q3 is connected to the high frequency oscillation module after passing through the twenty first resistor R21; a collector of the third transistor Q3 is connected to the 5V voltage terminal; an emitter of the third transistor Q3 is connected to an anode of the indicator light diode D5 after passing through the twenty second resistor R22, a cathode of the indicator light diode D5 is grounded.

In summary, the present application provides a luminous puzzle that can be induced by a wireless coil to emit light from puzzle blocks. Compared with the luminous puzzle in existing technology, the present application effectively protects the PCB inside the puzzle module by embedding the LED module into the paper board of the puzzle module, improves a seismic performance of the puzzle module, avoids the loosening and damage of the LED module component. An energy transfer principle on the puzzle is changed from an original contact connection to coil induction energy transfer, which can avoid a short circuit of metal contacts and improve a lifespan of the puzzle.

The present disclosure is not limited to the above-mentioned embodiments. If various modifications or variations of the present disclosure do not deviate from the spirit and scope of the present disclosure, and if these modifications and variations fall within the claims and equivalent technical scope of the present disclosure, the present disclosure is also intended to include these modifications and variations.

What is claimed is:

1. A wireless powered luminous puzzle, comprising: a positioning base plate and several puzzle modules;
each puzzle modules comprises:
a PVC board, configured to enhance a strength of the puzzle module;
a paper board, and
a TPE board, configured to print a pattern;
wherein a top surface of the PVC board is fixedly connected to a bottom surface of the paper board;
a top surface of the paper board is fixedly connected to a bottom surface of the TPE board;
an interior of the paper board is embedded with a LED module;
an interior of the positioning base plate is provided with a power supply circuit; the power supply circuit is inductively connected to the LED module.

2. The wireless powered luminous puzzle according to claim 1, wherein the LED module comprises a first induction coil, a current limit resistor, a filtering capacitor, a light-emitting diode, and a PCB circuit board;
two ends of the first induction coil are respectively connected to two ends of the filtering capacitor;
a cathode of the light-emitting diode is connected to one end of the filtering capacitor, an anode of the light-emitting diode is connected to the other end of the filtering capacitor after passing through the current limit resistor;
the first induction coil, the current limit resistor, the filtering capacitor, and the light-emitting diode are all fixedly connected to the PCB circuit board.

3. The wireless powered luminous puzzle according to claim 2, wherein an incised groove is provided on the PCB circuit board; the first induction coil is accommodated in the incised groove.

4. The wireless powered luminous puzzle according to claim 1, wherein the power supply circuit comprises: a switch module configured to connect to an external power source, a boost module configured to adjust a power supply voltage of the circuit, a high frequency oscillation module, an amplification-and-transmission module, a second induction coil configured to inductively connect with the puzzle module, and an indicator light module configured to indicate a working state of the circuit;
an output end of the switch module is connected to an input end of the boost module; an output end of the boost module is connected to a 12V voltage terminal;
a first output end of the high frequency oscillation module is connected to an input end of the amplification-and-transmission module;
an output end of the amplification-and-transmission module is connected to an input end of the second induction coil;
a control end of the indicator light module is connected to a second output end of the high frequency oscillation module.

5. The wireless powered luminous puzzle according to claim 4, wherein the high frequency oscillation module comprises: a latch chip, a first resistor, a second resistor, a third resistor, a fourth resistor, a fifth resistor, a first capacitor, a second capacitor, a third capacitor, a fourth capacitor, a fifth capacitor, and a crystal oscillator;
wherein a first pin of the latch chip is connected to a 5V voltage terminal after passing through the first resistor and the second resistor; the first pin of the latch chip is further grounded after passing through the first capacitor; the first pin of the latch chip is further connected to the control end of the indicator light module;
a second, fourth, sixth, eighth, and ninth pins of the latch chip are all connected to one end of the crystal oscillator after passing through the third resistor; one end of the crystal oscillator is further grounded after passing through the third capacitor, the other end of the crystal oscillator is grounded after passing through the fourth capacitor, the other end of the crystal oscillator is grounded after passing through the fifth capacitor;
a tenth pin of the latch chip is grounded;
an eleventh pin of the latch chip is connected to the other end of the crystal oscillator after passing through the fourth resistor;
a thirteenth, fifteenth, and seventeenth pins of the latch chip are all connected to a nineteenth pin thereof;
a twelfth, fourteenth, sixteenth, and eighteenth pins of the latch chip are all connected to the amplification-and-transmission module after passing through the fifth resistor;
a twentieth pin of the latch chip is grounded after passing through the second capacitor; the twentieth pin of the latch chip is further connected to the 5V voltage terminal.

6. The wireless powered luminous puzzle according to claim 4, wherein the amplification-and-transmission module comprises: a sixth capacitor, a seventh capacitor, an eighth capacitor, a ninth capacitor, a tenth capacitor, an eleventh capacitor, a twelfth capacitor, a thirteenth capacitor, a fourteenth capacitor, a fifteenth capacitor, a sixteenth capacitor, a seventeenth capacitor, a sixth resistor, a first inductor, a second inductor, a third inductor and a first MOS transistor;
a gate of the first MOS transistor is grounded after passing through the sixth resistor; the gate of the first MOS transistor is further connected to an output end of the high frequency oscillation module;
a source electrode of the first MOS transistor is grounded; a drain of the first MOS transistor is connected to a positive electrode of the first polar capacitor after passing through the first inductor; the positive electrode of the first polar capacitor is further connected to the 12V voltage terminal, a negative electrode of the first polar capacitor is grounded; the positive electrode of the first polar capacitor is further grounded after passing through the seventh capacitor, the positive electrode of the first polar capacitor is further grounded after passing through the sixth capacitor;
a drain of the first MOS transistor is grounded after passing through the eighth capacitor, the drain of the first MOS transistor is grounded after passing through the ninth capacitor;
the drain of the first MOS transistor is connected to one end of the second inductor;
the other end of the second inductor is grounded after passing through the tenth capacitor; the other end of the second inductor is grounded after passing through the eleventh capacitor; the other end of the second inductor is grounded after passing through the twelfth capacitor; the other end of the second inductor is further connected to one end of the third inductor;
the other end of the third inductor is grounded after passing through the thirteenth capacitor; the other end of the third inductor is grounded after passing through the fourteenth capacitor; the other end of the third inductor is connected to the second induction coil after passing through the fifteenth capacitor; the other end of the third inductor is connected to the second induction coil after passing through the sixteenth capacitor.

7. The wireless powered luminous puzzle according to claim 4, wherein the boost module comprises: a voltage regulation chip, a first diode, a second diode, a third diode, a second polar capacitor, a third polar capacitor, a fourth inductor, a first transistor, a second transistor, a seventeenth capacitor, an eighteenth capacitor, a nineteenth capacitor, a twentieth capacitor, a twenty first capacitor, a twenty second capacitor, a twenty third capacitor, a seventh resistor, an eighth resistor, a ninth resistor, a tenth resistor, an eleventh resistor, a twelfth resistor, a thirteenth resistor, a fourteenth resistor, a fifteenth resistor, a sixteenth resistor, a seventeenth resistor, an eighteenth resistor, a nineteenth resistor;
a first pin of the voltage regulation chip is grounded after passing through the sixteenth resistor; the first pin of the voltage regulation chip is connected to a collector of the first transistor after passing through the fifteenth resistor, the first pin of the voltage regulation chip is connected to a collector of the second transistor after passing through the seventeenth resistor;
an emitter of the first transistor is grounded, an emitter of the second transistor is grounded;
a base of the first transistor is grounded after passing through the thirteenth resistor; the base of the first transistor is further connected to the switch module after passing through the twelfth resistor;
a base of the second transistor is grounded after passing through the eighteenth resistor, the base of the second transistor is further connected to the switch module after passing through the nineteenth resistor;
a second pin of the voltage regulation chip is respectively connected to a cathode of the first diode, a cathode of the second diode, and a cathode of the third diode; a second pin of the voltage regulation chip is connected to the first pin of the voltage regulation chip after passing through the fourteenth resistor; the second pin of the voltage regulation chip is grounded after passing through the twenty third capacitor, the second pin of the voltage regulation chip is connected to a positive electrode of the third polar capacitor, a negative electrode of the third polar capacitor is grounded; the second pin of the voltage regulation chip is further connected to the 12V voltage terminal;
a third pin of the voltage regulation chip is connected to the 5V voltage terminal after passing through the eighth resistor; the third pin of the voltage regulation chip is grounded after sequentially passing through the eighth resistor and the seventeenth capacitor; the third pin of the voltage regulation chip is connected to a positive electrode of the second polar capacitor after passing through the eighth resistor, a negative electrode of the second polar capacitor is grounded;
a fourth pin of the voltage regulation chip is respectively connected to an anode of the first diode, an anode of the second diode, an anode of the third diode; the fourth pin of the voltage regulation chip is connected to the positive electrode of the second polar capacitor after passing through the fourth inductor, the fourth pin of the voltage regulation chip is grounded after sequentially passing through the seventh resistor and the eighteenth capacitor;
a fifth pin of the voltage regulation chip is grounded after passing through the twentieth capacitor; the fifth pin of the voltage regulation chip is grounded after passing through the ninth resistor;
a sixth pin of the voltage regulation chip is grounded after passing through the tenth resistor;
a seventh pin of the voltage regulation chip is grounded after sequentially passing through the eleventh resistor and the twenty first capacitor; the seventh pin of the voltage regulation chip is further grounded after passing through the twenty second capacitor; an eighth pin of the voltage regulation chip is grounded after passing through the nineteenth capacitor.

8. The wireless powered luminous puzzle according to claim 4, wherein the switch module comprises: a switch control chip, a normally open fuse switch, a Zener diode, a second MOS transistor, a twentieth resistor, a twenty fourth capacitor, and a connector configured to connect an external circuit;
a first pin of the switch control chip is grounded;
a second pin of the switch control chip is connected to a second pin of the connector;
a third pin of the switch control chip is connected to a first pin of the connector;
a fourth pin and seventh pin of the switch control chip are both connected to the boost module;
a fifth pin of the switch control chip is grounded after passing through the normally open fuse switch;
a sixth pin of the switch control chip is connected to a gate of the second MOS transistor, a source electrode of the second MOS transistor is connected to a fourth pin of the connector; a drain of the second MOS transistor is connected to the 5V voltage terminal;
an eighth pin of the switch control chip is connected to the fourth pin of the connector; the eighth pin of the switch control chip is grounded after passing through the twenty fourth capacitor, the eighth pin of the switch control chip is further connected to a cathode of the Zener diode, an anode of the Zener diode is grounded;
a third pin of the connector is grounded.

9. The wireless powered luminous puzzle according to claim 4, wherein the indicator light module comprises: a third transistor, a twenty first resistor, a twenty second resistor, and an indicator light diode;
a base of the third transistor is connected to the high frequency oscillation module after passing through the twenty first resistor;
a collector of the third transistor is connected to the 5V voltage terminal;
an emitter of the third transistor is connected to an anode of the indicator light diode after passing through the twenty second resistor, a cathode of the indicator light diode is grounded.
